(19) United States
(12) Patent Application Publication
(10) Pub. No.: US 2012/0256159 A1
(43) Pub. Date: Oct. 11, 2012

(54) LED Device Architecture Employing Novel Optical Coating and Method of Manufacture

(75) Inventor: Jamie Knapp, Mendon, MA (US)

(73) Assignee: Newport Corporation, Irvine, CA (US)

(21) Appl. No.: 13/513,823

(22) PCT Filed: Apr. 1, 2010
(86) PCT No.: PCT/US2010/001010

§ 371 Date: Jun. 4, 2012

Related U.S. Application Data
(60) Provisional application No. 61/335,160, filed on Dec. 30, 2009.

(51) Int. Cl. H01L 33/04

(52) U.S. Cl. 257/9; 438/26; 257/E33.008

(57) ABSTRACT

An improved LED device is disclosed and includes at least one active layer in communication with an energy source and configured to emit a first electromagnetic signal within a first wavelength range and at least a second electromagnetic signal within at least a second wavelength range, a substrate configured to support the active layer, at least one coating layer formed from alternating layers of silicon carbide and alumina applied to a surface of the substrate, the coating layer configured to reflect at least 95% of the first electromagnetic signal at the first wavelength range and transmit at least 95% of the second electromagnetic signal at the second wavelength range, at least one metal layer applied to the coating layer and configured to transmit the second electromagnetic signal at the second wavelength range therethrough, and an encapsulation device positioned to encapsulate the active layer.

### BACKGROUND

Light emitting diodes (hereinafter LED) are electronic light sources having relatively intense luminescent output in the UV, visible and infrared wavelengths. Presently, there are many advantages of these devices over conventional lighting methods such as incandescent sources. Exemplary advantages of LED devices include lower energy consumption, extended lifetimes, improved robustness, smaller size and quicker switching. Red, green and blue LEDs have been commonplace for many years and are presently used in a multitude of applications including display lighting, biomedical fluorescence instrumentation and a vast array of commercial applications. Recently, the use of new high output white LEDs have grown significantly. Common uses for these white-light LEDs include architectural applications, automotive applications and other lighting uses. To be competitive with other lighting sources, white-light LEDs must achieve optimal efficiency. Ideally, high power LED (hereinafter HPLED) manufacturers hope to provide white-light LEDs having efficiencies of about 150 L/W or greater.

White LEDs are generally produced by altering the structure of blue LEDs. Blue LEDs are manufactured from wide bandgap semiconductor epitaxial materials such as Indium Gallium Nitride (InGaN). By employing fluorescence, the blue spectral output of the LED is converted to white light by the absorption of the blue photons into the encapsulant, which subsequently fluoresces white. FIGS. 1-3 show a cross-sectional view of a typical white light LED. As shown, the LED device 1 includes at least one light-producing active layer 3 positioned on a substrate 5. Exemplary substrates typically include silica substrates and sapphire substrates, as well as other materials. A reflective metal layer 7 is applied to a surface of the substrate 5. Further, a doped encapsulation device 9 is applied to the structure thereby sealing the light-producing active layer 3 within the structure. Typical doping materials include phosphor and other materials configured to fluoresce to produce white light when illuminated with a specific wavelength. For example, phosphor may be configured to fluoresce when illuminated with light 11 having a wavelength of about 450 nm.

As shown in FIG. 2, the blue spectral output of the LED device 1 is multidirectional. Some electromagnetic radiation 11a having a wavelength capable of resulting in fluorescence is emitted directly to the doped encapsulation device 9 thereby causing the doping material to fluoresce generally white light. Further, due to the multidirectional output of the light-producing active layer 3, rear-emitted light 11b is reflected by the metal layer 7 applied to the substrate 5 and direct to the encapsulation device 9. This reflected output 13b also results in fluoresces the doping material of the encapsulation device 9. While the metal layer 7 is somewhat useful in increasing the output of the LED device 1, a number of shortcomings have been identified. For example, the metal layer 7 may reflect about 85% to 90% of the incident light capable of fluorescing the doping materials in the encapsulation device 9. As such, the efficiency (e.g. L/W) of these LED devices 1 is not optimal. Ideally, the metal layer 7 would have a reflectivity approaching 100% at a wavelength to effect fluorescents of the doping materials, which to date has proven to be unattainable. As stated above, presently available devices include an aluminum layer 7 capable of reflecting about 85% to about 90% of incident light. Further, as shown in FIG. 2, some of the rear-emitted light 11c may be incident on the reflective aluminum layer 7 at various angles. Ideally, the reflective layer 7 would be capable of reflecting about 100% of the rear-emitted light 11c at all possible angles of incidence, thereby directing the reflected angular rear-emitted light 13c to the encapsulation device 9 and increasing device efficiency. Unfortunately, current-art metal reflector layers 7 suffer additional reflective losses at such extreme angles, resulting in an even poorer LED light output.

In addition to reflecting the rear-emitted light, the metal reflective material 7 may also behave as a heat-sink to enhance the thermal characteristics of the device. To this end, the LED subcomponents forming the LED device may be manufactured from materials having thermal characteristics configured conduct heat generated during use to a heat sink or material substrate supporting the LED device. For example, the reflective material 7 may comprise copper, silver or aluminum and may be configured to enable the efficient transfer of heat from the substrate 5 to a mounting structure (not shown). For example, as shown in FIG. 3 undesirable infrared radiation 15 may be produced by the light-producing active layer 3 when an electrical charge is applied thereto. In one embodiment, the substrate 5 is configured to dissipate the heat therethrough. As such, the substrate 5 may form a heat sink. Further, the reflective layer 7 applied to the substrate 5 may also be configured to transfer heat therethrough. However, at least some infrared radiation 15 may be reflected by the reflective material 7 or at the substrate-reflective material interface. For example, in some applications approximately 20% of the infrared radiation 15 may be reflected back to the light-producing active layer 3 by the reflective layer 7 or the substrate-reflective layer interface. This reflected infrared radiation 17 may result in a degradation of the performance of the LED device 1. In severe cases, the reflected infrared radiation 17 may result in the catastrophic failure of the LED device 1 due to excessive heating.

Thus, in light of the foregoing, there is an ongoing need high power LED devices offering higher efficiency than presently available.

### SUMMARY

The present application disclosed various embodiments of improved LED device architectures and various methods for the manufacture thereof. Unlike prior art devices, the device architectures disclosed herein include at least one coating layer applied to the substrate configured to improve device efficiency and brightness.

In one embodiment, the present application disclosed an improved LED device and includes a substrate configured to support the active layer, at least one coating layer applied to a surface of the substrate, the coating layer formed from alternating thin film layers of silicon carbide and alumina, the coating layer configured to reflect at least 95% of a first electromagnetic signal at a first wavelength range and transmit at least 95% of a second electromagnetic signal at a second wavelength range, at least one active layer positioned on the substrate and in communication with an energy source configured to emit the first electromagnetic signal within the first wavelength range and at least the second electromagnetic signal within at least the second wavelength range, and an encapsulation device positioned to encapsulate the active layer.

In another embodiment, the present application discloses an improved LED device and includes a substrate configured to support the active layer, at least one coating layer applied to a surface of the substrate, the coating layer formed from alternating thin film layers of silicon carbide and alumina, the coating layer configured to reflect at least 95% of a first electromagnetic signal at a first wavelength range at all angles from about 0 degree to about 90 degrees and transmit at least 95% and transmit at least 95% of a second electromagnetic signal at a second wavelength range, at least one metal layer applied to the coating layer, at least one active layer positioned on the substrate and in communication with an energy source configured to emit the first electromagnetic signal within the first wavelength range and at least the second electromagnetic signal within at least the second wavelength range, and an encapsulation device positioned to encapsulate the active layer.

The present application also disclosed various methods of manufacturing LED devices. In one embodiment, the present application discloses a method of manufacturing a LED device which includes applying at least one coating layer formed from alternating layers of silicon carbide and alumina to a substrate, the coating configured to reflect at least 95% of a first electromagnetic signal at a first wavelength range and transmit at least 95% of a second electromagnetic signal at a second wavelength range to a surface of the substrate, growing an epitaxial layer capable of emitting electromagnetic radiation within the first wavelength range and at least the second electromagnetic radiation within at least the second wavelength range when subjected to an electric charge on the substrate, and encapsulating at least the active layer within an encapsulation device.

In another embodiment, the present application discloses a method of manufacturing a LED device and includes providing a silicon carbide substrate, growing an epitaxial layer capable of emitting electromagnetic radiation within a first wavelength range and at least a second electromagnetic radiation within at least a second wavelength range when subjected to an electric charge on the substrate, applying at least one coating layer formed from alternating layers of silicon carbide and alumina to a substrate, the coating configured to reflect at least 95% of the first electromagnetic signal at the first wavelength range and transmit at least 95% of the second electromagnetic signal at the second wavelength range to a surface of the substrate, and encapsulating at least the active layer within an encapsulation device.

Other features and advantages of the embodiments of the improved LED device architectures as disclosed herein will become apparent from a consideration of the following detailed description.

### BRIEF DESCRIPTION OF THE DRAWINGS

Various improved performance LED device architectures will be explained in more detail by way of the accompanying drawings, wherein:

FIG. 1 shows a cross-sectional view of an embodiment of a prior art LED device;

FIG. 2 shows a cross-sectional view of an embodiment of a prior art LED device during use wherein a portion of the electromagnetic radiation within a first wavelength range may be reflected by the metal layer;

FIG. 3 a cross-sectional view of an embodiment of a prior art LED device during use wherein a portion of the electromagnetic radiation within a second wavelength;

FIG. 4 shows a cross-sectional view of an embodiment of a novel LED device architecture having a coating layer applied to a surface of the substrate, the coating layer configured to improve the reflectance of the first electromagnetic radiation within a first wavelength range; and

FIG. 5 shows graphically the reflectance performance of the novel LED device architecture having a SiC—Al₂O₃ coating layer as compared with the reflectance performance of the novel LED device architecture having a TiO₂—SiO₂ coating layer.

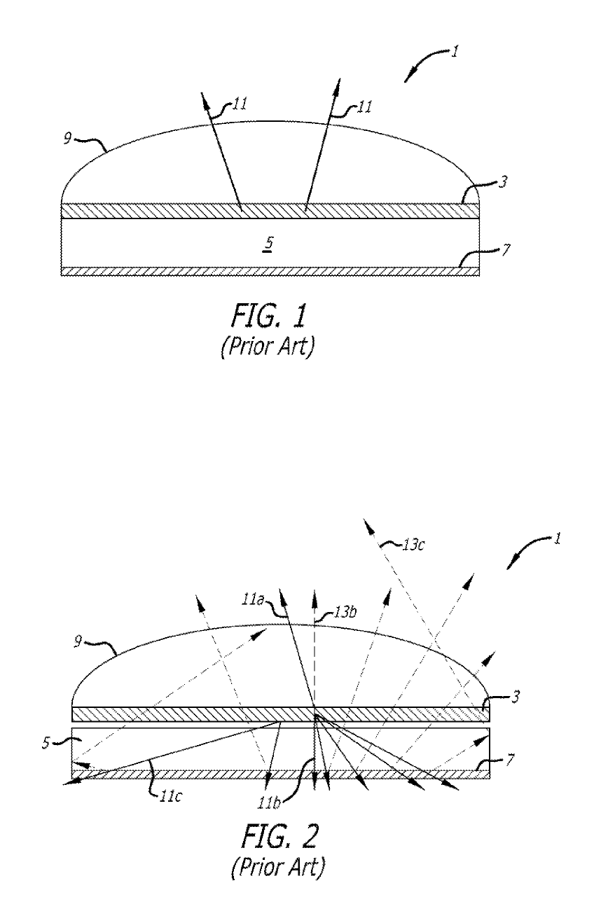

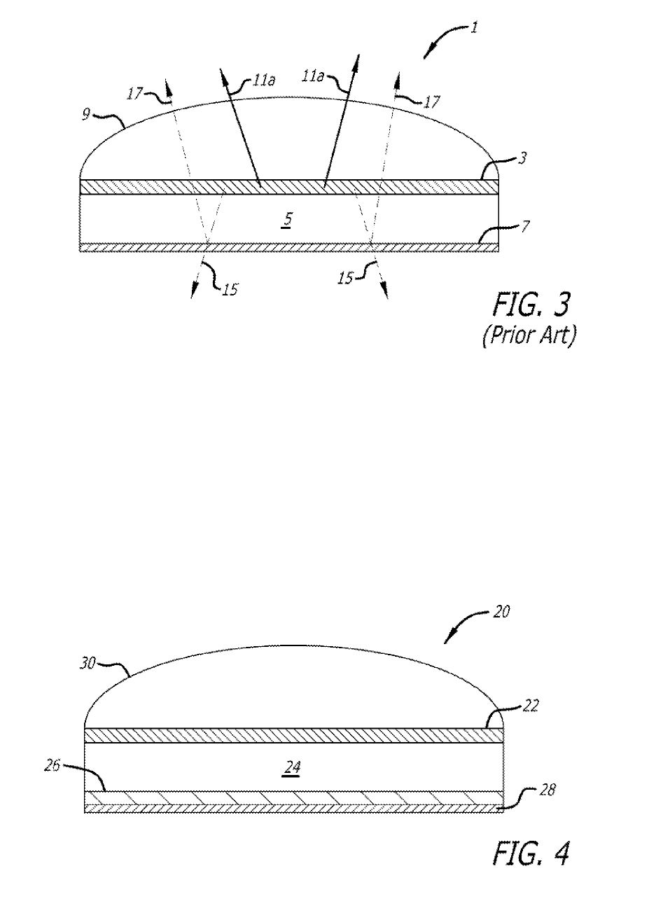

### DETAILED DESCRIPTION

FIG. 4 shows a cross-sectional view of an embodiment of a high power LED device. As shown, the improved LED device 20 includes at least one active layer 22 positioned on or proximal to at least one substrate 24. In one embodiment, the active layer 22 comprises a light-producing active layer. Optionally, a single light-producing active layer 22 may be positioned on the substrate 24. Optionally, any number of active layers 22 may be positioned on the substrate 24. As such, the active layer 22 may comprise a multi quantum well device or structure. It should be noted that the active layer 22 may be in communication with at least one energy source and, thus, may include at least one electrical connection device (not shown) configured to provide at least one electrical signal to thereto. Further, in one embodiment the substrate 24 comprises a silicon carbide substrate. Optionally, any variety of materials may be used to form the substrate 24. Exemplary substrate materials include, without limitations, silica, sapphire, various composite materials, and the like. Further, the substrate 24 may be configured to transmit substantially all electromagnetic radiation therethrough.

Referring again to FIG. 4, like the prior art devices, the present LED device 20 includes a metal layer 28 applied thereto. Optionally, the LED device 20 may be manufactured without the metal layer 28. As such, the LED device 20 may include a thermal paste or similar bonding agent configured to couple the LED device 20 to a material substrate (not shown). Exemplary materials substrates include, without limitations, heat sinks, printed circuit boards and the like. Like the prior art devices, the metal layer 28 or thermal paste, if present, is configured to reflect rear-emitted electromagnetic radiation to at least one doped encapsulation device 30 positioned proximate to the active layer 22, while aiding the effective removal of heat from the LED device 20. However, unlike prior art devices, the improved LED device 20 disclosed in the present application includes at least one coating layer 26 applied to a surface of the substrate 24. The inclusion of the coating layer 26 on the improved LED device 20 disclosed in the present application is configured to achieve optimum light reflectivity of substantially all light within substrate 24, at all possible angles of incidence 0 degrees-90 degrees, thereby increasing the output of the LED device 20.

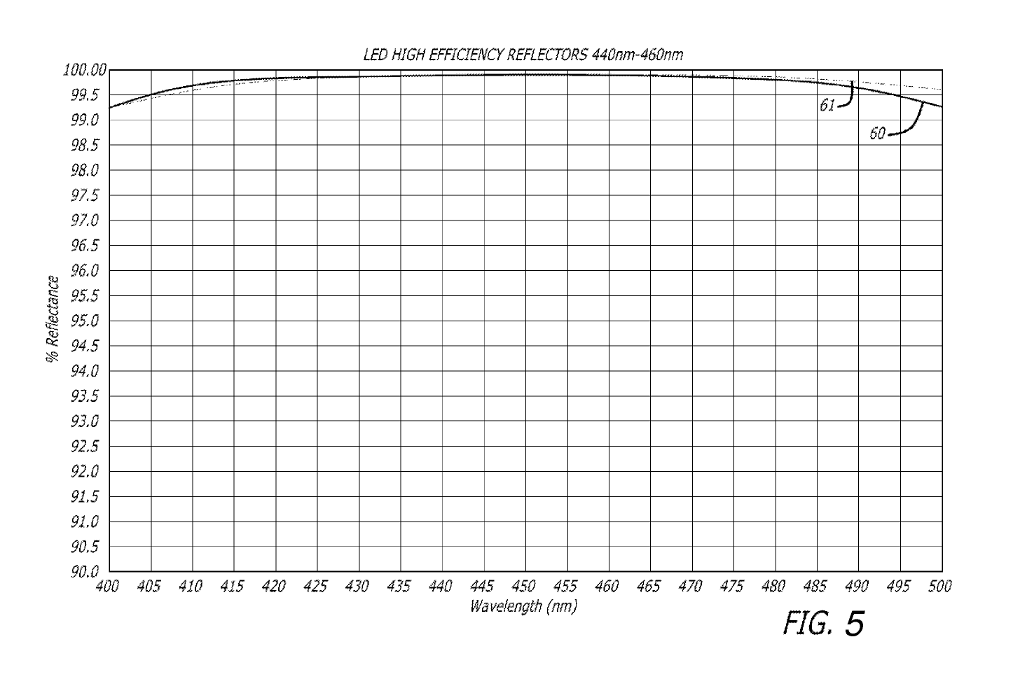

Optionally, the coating layer 26 may be applied to any surface of the substrate 24. For example, FIG. 5 shows an LED configuration having a coating layer 26 positioned proximate to the active layer 22. In contrast, FIG. 6 shows an LED configuration having a first coating layer 26 located proximate to the active layer 22 and a second coating layer 26 positioned proximate to the substrate 24 and metal layer 28. Referring to FIGS. 5 and 6, positioning a coating layer 26 proximate to the active layer 22 may increase LED illumination by eliminating light losses due to internal substrate light scatter and light-piping (losses through the LED chip edges). As a result, the present embodiment offers improved performance over prior art devices by efficiently emitting the desired UV or visible light produced by the active layer 22 therethrough while reflecting the damaging longer wavelength infrared radiation through the substrate 24 to be eventually removed by via the metal layer 28 and/or a heatsink coupled thereto. In one embodiment, the method for applying the coating layer 26 produces a stable, hard, dense, nonporous amorphous coating that does not substantially absorb moisture, which could otherwise compromise device quality, longevity and performance.

Referring again to FIG. 4, the coating layer 26 may be comprised alternating layers of a material having a high index of refraction (hereinafter “high index”) and a material having a low index of refraction (hereinafter “low index”). In one embodiment, the coating layer 26 consists of the novel combination of two high-thermal conductivity materials: alumina (sapphire) and silicon carbide. During use, the maximum temperature at which a multilayer optical coating may be exposed to may be limited by the differences in the coefficient of thermal expansion and contraction of the optical coating materials used (Table 1). Large differences may result in the reduction of maximum exposure temperature. For a typical refractory-metal oxide based optical coating (such as quartz and titanium dioxide), the ratio of their coefficients of thermal expansion is large (15:1). At elevated temperatures (e.g. above 600 degrees C.), these materials may expand and contract differently, possibly leading to coating failure. In contrast, the use of thin films of silicon carbide and alumina may be exposed to extreme temperatures of 1000 degrees C. or higher without damage due the their near equal coefficients of thermal expansion. Further, as the coefficients of thermal expansion between the substrate, silicon carbide, and alumina are nearly equal, virgin substrates (e.g. sapphire or silicon carbide) may be pre-coated with alternating silicon carbide/alumina coating layer before the epitaxy takes place. This option offers significant benefits during the manufacture of LEDs, including, but not limited to, the stress balancing (flattening) of distorted substrates and the reduction of risk (any errors can be remedied by polishing off this coating, and repeating the process without risking damage to the costly epitaxial layers).

The coating layer 26 may be configured to reflect at least 90% of electromagnetic radiation having wavelength from about 430 nm to about 500 nm at all angles from about 0 degree to about 90 degrees. In another embodiment, the coating layer 26 may be configured to reflect at least about 95% of electromagnetic radiation having wavelength from about 430 nm to about 500 nm at all angles from about 0 degree to about 90 degrees. In still another embodiment, the coating layer 26 may be configured to reflect at least about 98% of electromagnetic radiation having wavelength from about 430 nm to about 500 nm at all angles from about 0 degree to about 90 degrees. In another embodiment, the coating layer 26 may be configured to reflect at least about 99% of electromagnetic radiation having wavelength from about 430 nm to about 500 nm at all angles from about 0 degree to about 90 degrees. As such, the coating layer 26 may be configured to optimize reflection of any desired wavelength band at all incident angles from about 0 degree to about 90 degrees. Those skilled in the art will appreciate that the coating layer 26 may be configured to selectively reflect at least about 95% of electromagnetic radiation at all angles from about 0 degree to about 90 degrees within any variety of desired wavelength ranges.

In addition to enhancing the reflectivity of the reflective aluminum layer 28, in some embodiments it may be desirable to maximize the extraction of heat from the LED device 20, thereby decreasing the likelihood of heat-related failure. Such improved thermal management also allows for an increase in the amount of power that can be applied to the LED device 20, leading to a further increase in brightness. The heat generated by the active layer 22 during use may be directed through substrate 24 to be eventually absorbed and dissipated by the metal layer 28. As stated above, the coating layer 26 may comprise alternating thin films of low index of refraction materials and high index of refraction materials. Such thin films may be of physical thicknesses ranging from about 5 nm to about 1000 nm each. Table 1 summarizes the reflectance and thermal behavior of typical thin-film optical materials which may be used with the improved LED device disclosed herein. In one embodiment, the sequence of low index and high index materials is configured to optimize the reflectivity. In another embodiment, the optical coating layer 26 is configured to optimize heat transfer through the optical coating layer 26 by employing high thermal conductivity thin film materials such as alumina and silicon carbide. In still another embodiment, the optical coating layer 26 is configured to optimize reflectivity and heat transfer through the coating layer 26 also by employing high thermal conductivity thin film materials. In still another embodiment, the optical coating layer 26 is configured to optimize reflectivity and heat transfer through the coating layer 26 also by employing high thermal conductivity thin film materials along with the use of a high thermal conductivity copper or copper alloy heat sink rather than standard aluminum.

TABLE 1

| | THERMAL | REFLEC- | COEFFICIENT |
|---|---|---|---|
| | CONDUC- | TIVITY | OF THERMAL |
| MATERIAL | TIVITY | (450 nm) | EXPANSION |
| Typical Low Index of | 9.5 W/m K | | 0.59 × 10⁻⁶/° C. |
| Refraction | | | |
| Quartz (SiO2) | | | |
| Typical High Index of | 11.7 W/m K | | 9.0 × 10⁻⁶/° C. |
| Refraction | | | |
| Titanium Dioxide | | | |
| (TiO2) | | | |
| SiO2 + TiO2 | | >99% | |
| multilayer coating | | | |
| Low Index of | 42 W/m K | | 4.3 × 10⁻⁶/° C. |
| Refraction Material | | | |
| Alumina (Al2O3) | | | |
| High Index of | 120 W/m K | | 4.0 × 10⁻⁶/° C. |
| Refraction Material | | | |
| Silicon Carbide (SiC) | | | |
| Al2O3 + SiC | | >99% | |
| Multilayer coating | | | |
| Aluminum Metal | 237 W/m K | <90% | |
| Copper Metal | 400 W/m K | <50% | |

As described in Table 1, the average thermal conductivity of a current-art multilayer optical coating (SiO2/TiO2 for example) is about 10.6 W/m K. In contrast, the thermal conductivity of the multilayer optical coating (alumina/silicon carbide) disclosed in the present application is about 81 W/m K, yielding an approximately 800% improvement in heat conduction over prior art architectures. In addition, as also described in Table 1, the current-art heat sink material generally employed for LEDs (aluminum) has a lower thermal conductivity as compared to an optional heat sink produced with copper. By employing copper (or copper containing alloy) as this heat sink material, the net thermal improvement of almost 1600% when combined with the alumina/silicon carbide optical coating, as compared with prior art architectures.

FIG. 5 is an example of the optical performance (percent reflection versus wavelength) of the optical coating 60 disclosed in the present application as compared with an optical coating formed from refractory metal oxides 61 (SiO2 and TiO2). Using the same optical coating design (same sequence of high and low thin films with the same physical thicknesses), the optical performance of this new multilayer alumina (Al₂O₃) and silicon carbide (SiC) based coating offers substantially equal reflection within the range 440 nm-460 nm as that offered by a refractory metal oxide coating. As such, the optical coating disclosed here provides improved net LED efficiency (L/W) by optically maximizing light output (minimizing light losses) while providing a high thermal conductivity path for efficient conductive heat management over current device architectures.

Referring again to FIG. 4, in one embodiment, the manufacture of the LED device 20 may begin with growing at least one active layer 22 onto at least one substrate 24. In one embodiment, the active layer 22 is formed through an epitaxy process of MOCVD (metal organic chemical vapor deposition); although those skilled in the art will appreciate that any variety of techniques may be used to form the active layer 22 on the substrate 24. Typically, the MOCVD process will grow the active layer 22 at a very high substrate temperature (for example 1000 degrees Celsius). Thereafter, with the active layer 22 provided on the substrate 24 the LED device may be processed into final configuration. Final processing may include applying at least one optical coating layer 26 (layers of alumina and silicon carbide) to the surface of the substrate 24 opposite the active layer 22. Optionally, one or more metal layers 28 may be applied to the optical coating layer 26.

In the alternative, unlike optical coatings using conventional refractory metal oxides, the alumina and silicon carbide materials forming the optical coating layer 26 as described herein can withstand the extreme temperature of the epitaxial MOCVD process. As such, the optical coating layer 26 of the present application may be applied to the substrate 24 prior to MOCVD process, unlike standard refractory-metal oxide based optical coatings which must be deposited afterwards. Thereafter, the active layer 22 may be grown on the optically coated substrate 24. In contrast, if standard coatings (refractory metal oxides) were exposed to such an extreme temperatures, the standard coating would suffer cracking, peeling, buckling and crazing. Table 2 details the thermal characteristics of the alumina-silicon carbide based optical coating as compared with an exemplary refractory metal oxide based coating.

TABLE 2

| | COEFFICIENT |
|---|---|
| | OF THERMAL |
| MATERIAL | EXPANSION |
| Typical Low Index of Refraction | 0.59 × 10⁻⁶/° C. |
| Quartz (SiO2) | |
| Typical High Index of Refraction | 9.0 × 10⁻⁶/° C. |
| Titanium Dioxide (TiO2) | |
| Low Index of Refraction Material of | 4.3 × 10⁻⁶/° C. |
| Invention | |
| Alumina (Sapphire) Al2O3 | |
| High Index of Refraction Material of | 4.0 × 10⁻⁶/° C. |
| Invention | |
| Silicon Carbide (SiC) | |

The maximum temperature at which a multilayer optical coating can be exposed to is limited by the differences in the thermal expansion and contraction of the optical coating materials used (in addition to the difference in thermal expansion of the coating as compared to the substrate). Large differences results in the reduction of this maximum temperature allowed. For the exemplary refractory-metal oxide based optical coating (such as quartz and titanium dioxide), the ratio of their coefficients of thermal expansion is extremely large (15:1). At elevated temperatures, differences in the coefficients of thermal expansion often lead to interlayer coating failure. Further, the ratio of their coefficients of thermal expansion as compared to the underlying sapphire substrate is also very high (2:1 for TiO2 on sapphire and 7:1 for SiO2 on sapphire), which may also lead to coating delamination failures when exposed to elevated temperatures. As a result, the typical maximum exposure temperatures for LED devices using refractory metal oxide based optical coatings are 450-550 degrees C., far lower than the 1000 degree C. temperature of the epitaxy process. In contrast, the use of alumina and silicon carbide to form the optical coating layer 26 as described herein allows the optical coating layer 26 to be exposed to the extreme epitaxy temperature without degradation due to their similar coefficients of thermal expansion. The ratio of their expansion coefficients is only 1.07:1. Further, the ratio of alumina to its underlying sapphire substrate is 1:1 while the ratio of silicon carbide to its underlying sapphire substrate is 1.07:1. As a result, virgin sapphire substrates can be pre-coated with the alumina-silicon carbide coating layer 26 before the epitaxy takes place. Further, any errors occurring ion the coating process may be remedied by polishing off this coating, and repeating the coating process. As such, manufacturing risks are minimized. Thereafter, the pre-coated substrates may be subsequently subjected to the high temperature MOCVD process for epitaxy growth of active layer 22, followed by final device processing.

As stated above and shown in FIG. 4, the coating layer 26 may be configured to reflect substantially all light of a first wavelength range while transmitting substantially all light of a second wavelength range therethrough. For example, in one embodiment coating layer 26 may be configured to reflect at least 90% of electromagnetic radiation having wavelength from about 430 nm to about 500 nm while transmitting at least 90% of electromagnetic radiation having a wavelength greater than about 750 nm. In another embodiment, the coating layer 26 may be configured to reflect at least about 95% of electromagnetic radiation having wavelength from about 430 nm to about 500 nm while transmitting at least 95% of electromagnetic radiation having a wavelength greater than about 500 nm. In still another embodiment, the coating layer 26 may be configured to reflect at least about 98% of electromagnetic radiation having wavelength from about 430 nm to about 500 nm while transmitting at least 98% of electromagnetic radiation having a wavelength greater than about 750 nm. In another embodiment, the coating layer 26 may be configured to reflect at least about 99% of electromagnetic radiation having wavelength from about 430 nm to about 500 nm while transmitting at least 99% of electromagnetic radiation having a wavelength greater than about 750 nm. As such, the coating layer 26 may be configured to optimize reflection of a desired first wavelength to improve the fluorescence of the doping material in the encapsulation device 30 while reducing the back reflection of electromagnetic radiation at the second wavelength (e.g. infrared radiation) at the substrate-metal layer interface, thereby improving the transfer of heat through the metal layer 28.

As shown in FIG. 4, at least one encapsulation device 30 may be positioned on the improved LED device 20. The encapsulation device 30 may include any variety of dopants or doping materials therein. For example, in one embodiment the encapsulation device 30 includes phosphor configured to fluoresce white light when irradiated with electromagnetic radiation having a wavelength range of about 400 nm to about 525 nm. In another embodiment, the encapsulation device including one or more doping materials configured to fluoresce and emit light at any variety of wavelengths when illuminated with electromagnetic radiation of any wavelength emitted by the active layer 22. Optionally, multiple doping materials may be used simultaneously. The encapsulation device 30 may be formed in any variety of ways. For example, in one embodiment the encapsulation device 30 comprises an epoxy material applied as a fluid to the active layer 22. In another embodiment, the encapsulation device 30 may comprise a physical structure bonded to or otherwise secured to the active layer 22. For example, in one embodiment the encapsulation device 30 may form an optical lens. Exemplary optical lenses include, without limitations, concave lenses, convex lenses, fresnel lenses, and the like. In one embodiment, the encapsulation device 30 is configured to couple to the improved LED device 20 in sealed relation. For example, the encapsulation device 30 may be coupled to the improved LED device 20 in hermetically sealed relation.

### Example

A multilayer dielectric optical coating 26 is uniformly applied directly onto the entire rear surface of a 2″DIA sapphire substrate 24 upon which individual LED multilayer semiconductor elements 22 were epitaxially grown on its upper surface (individual die sizes were less than about 1.0 mm square). In this case, the LED emits a blue light within the wavelength range 440 nm-460 nm The optical coating 26 is applied before the encapsulation device 30 is applied. Alternating high-and-low refractive index thin films having physical thicknesses chosen to optimize the resultant spectral performance desired are deposited (maximum optical reflection within a select visible wavelength band 440 nm-460 nm). In this specific case, high thermal conductivity silicon carbide is employed for the high index material (refractive index about 2.8 at 450 nm) and high thermal conductivity alumina is employed as the low index material (refractive index about 1.6 at 450 nm). A representative multilayer optical coating is as follows:

Epitaxial Semiconductor LED Layers/Sapphire Substrate/30.87H 68.96L 28.8H (21.65H 76.27L 21.65H)6 17.85H 200.79L

Where the symbols L and H signify the physical thicknesses (in nm) of L (low index alumina) and H (high index SiC) thin films. A representative reflectance performance spectral curve 60 as a function of wavelength is illustrated in FIG. 5.

Those skilled in the art will appreciate that the silicon carbide/alumina coating described herein may be used in any variety of optical applications. For example, the silicon carbide/alumina coating described herein is particularly useful when applied to silicon carbide and/or sapphire substrates due to thermal matching.

While particular forms of embodiments have been illustrated and described, it will be apparent that various modifications can be made without departing from the spirit and scope of the embodiments of the invention. Accordingly, it is not intended that the invention be limited by the forgoing detailed description

1. An improved LED device, comprising:
a substrate;
at least one coating layer applied to a surface of the substrate, the coating layer formed from alternating thin film layers of alumina and silicon carbide, the coating layer configured to reflect at least 95% of a first electromagnetic signal at a first wavelength range and transmit at least 95% of a second electromagnetic signal at a second wavelength range;
at least one active layer positioned on the substrate and in communication with an energy source configured to emit the first electromagnetic signal within the first wavelength range and at least the second electromagnetic signal within at least the second wavelength range; and
an encapsulation device positioned to encapsulate the active layer.

2. The device of claim 1 wherein the substrate comprises silicon carbide.

3. The device of claim 1 wherein the substrate comprises sapphire.

4. The device of claim 1 wherein the first wavelength range is from about 430 nm to about 500 nm.

5. The device of claim 1 wherein the second wavelength is greater than about 500 nm.

6. The device of claim 1 wherein the active layer comprises a multi-quantum well device.

7. The device of claim 1 further comprising a first coating layer positioned between the active layer and the substrate and at least a second coating layer positioned on a surface opposing the surface having the active layer applied thereto.

8. The device of claim 1 wherein the encapsulation device includes at least one dopant therein.

9. The device of claim 8 wherein the dopant is configured to fluoresce when illuminated with the first electromagnetic signal within the first wavelength range.

10. The device of claim 8 wherein the dopant comprises phosphor.

11. The device of claim 1 further comprising a metal layer applied to the coating layer.

12. The device of claim 11 wherein the metal layer comprises aluminum,

13. The device of claim 11 wherein the metal layer comprises copper.

14. An improved LED device, comprising:
a substrate;
at least one coating layer applied to a surface of the substrate, the coating layer formed from alternating thin film layers of alumina and silicon carbide, the coating layer configured to reflect at least 95% of a first electromagnetic signal at a first wavelength range at all angles from about 0 degree to about 90 degrees and transmit at least 95% and transmit at least 95% of a second electromagnetic signal at a second wavelength range;
at least one metal layer applied to the coating layer;
at least one active layer positioned on the substrate and in communication with an energy source configured to emit the first electromagnetic signal within the first wavelength range and at least the second electromagnetic signal within at least the second wavelength range; and
an encapsulation device positioned to encapsulate the active layer.

15. The device of claim 14 wherein the substrate comprises silicon carbide.

16. The device of claim 14 wherein the substrate comprises sapphire.

17. The device of claim 14 wherein the first wavelength range is from about 430 nm to about 500 nm.

18. The device of claim 14 wherein the second wavelength is greater than about 500 nm.

19. The device of claim 14 wherein the active layer comprises a multi-quantum well device.

20. The device of claim 14 further comprising a first coating layer positioned between the active layer and the substrate and at least a second coating layer positioned on a surface opposing the surface having the active layer applied thereto.

21. The device of claim 14 wherein the encapsulation device includes at least one dopant therein.

22. The device of claim 21 wherein the dopant is configured to fluoresce when illuminated with the first electromagnetic signal within the first wavelength range.

23. The device of claim 21 wherein the dopant comprises phosphor.

24. The device of claim 14 wherein the metal layer comprises aluminum,

25. The device of claim 14 wherein the metal layer comprises copper.

26. A method of manufacturing a LED device, comprising:
applying at least one coating layer formed from alternating layers of alumina and silicon carbide to a substrate, the coating configured to reflect at least 95% of a first electromagnetic signal at a first wavelength range and transmit at least 95% of a second electromagnetic signal at a second wavelength range to a surface of the substrate;
growing an epitaxial layer capable of emitting electromagnetic radiation within the first wavelength range and at least the second electromagnetic radiation within at least the second wavelength range when subjected to an electric charge on the substrate; and
encapsulating at least the active layer within an encapsulation device.

27. The method of claim 26 further comprising pre-stressing the substrate with the coating layer to compensate for stress from the application of the epitaxial layer.

28. The method of claim 26 further comprising applying a metal layer to the coating layer.

29. The method of claim 26 further comprising applying a thermal paste to the coating layer to affix the LED device to material substrate.

30. A method of manufacturing a LED device, comprising:
providing a silicon carbide substrate;
growing an epitaxial layer capable of emitting electromagnetic radiation within a first wavelength range and at least a second electromagnetic radiation within at least a second wavelength range when subjected to an electric charge on the substrate;
applying at least one coating layer formed from alternating layers of alumina and silicon carbide to a substrate, the coating configured to reflect at least 95% of the first electromagnetic signal at the first wavelength range and transmit at least 95% of the second electromagnetic signal at the second wavelength range to a surface of the substrate; and
encapsulating at least the active layer within an encapsulation device.

31. The method of claim 30 further comprising stressing the substrate with the coating layer to compensate for stress from the application of the epitaxial layer.

32. The method of claim 30 further comprising applying a metal layer to the coating layer.

33. The method of claim 30 further comprising applying a thermal paste to the coating layer to affix the LED device to material substrate.
